(19) United States
(12) Patent Application Publication
(10) Pub. No.: US 2023/0060965 A1
(43) Pub. Date: Mar. 2, 2023

(54) INTEGRATED BUFFER AND SEMICONDUCTOR MATERIALS

(71) Applicant: LUX SEMICONDUCTORS, INC., Albany, NY (US)

(72) Inventors: Shane T. McMAHON, Albany, NY (US); Graeme HOUSSER, Albany, NY (US); Lewis R. HABER, Albany, NY (US)

(73) Assignee: LUX SEMICONDUCTORS, INC., Albany, NY (US)

(21) Appl. No.: 17/657,850

(22) PCT Filed: Oct. 5, 2020
(86) PCT No.: PCT/US20/54245

§ 371 Date: Apr. 4, 2022

Related U.S. Application Data
(60) Provisional application No. 62/910,076, filed on Oct. 3, 2019.

(51) Int. Cl. H01L 23/528; H01L 23/532; H01L 23/14; H01L 23/31

(52) U.S. Cl. CPC H01L 23/5283; H01L 23/53209; H01L 23/142; H01L 23/3157

(57) ABSTRACT

A device includes an electrically conductive substrate, one or more intermediate layer(s) in contact with the electrically conductive substrate and/or one or more interconnect layer, and a surface mounted electrical component contacting the interconnect layer.

### CROSS-REFERENCE TO RELATED APPLICATIONS

This application is a national stage filing under 371 of International Application No. PCT/US2020/054245 filed Oct. 5, 2020, published on Apr. 8, 2021 as WO2021/067927 and which claims priority from U.S. Provisional Application No. 62/910,076 filed Oct. 3, 2019, the entire disclosures of which are incorporated herein by reference.

### BACKGROUND OF THE INVENTION

The present invention relates, generally, to the integration and structural architecture of thin films and devices, and more specifically to the integration and structural architecture of thin film intermediate layers, thin film semiconductors, patterned devices, and surface mounted devices, on an electrically conductive substrate.

As the density of transistors in semiconductor chips increases, so does the density of the respective input/output (I/O) connections. With the spacing, or pitch, between these I/O connections decreasing as a result, it becomes increasingly difficult to connect the chip to an external circuit. The patterning processes used to create printed circuit board (PCB) interconnects, cannot match the fine pitch resolution of chip level interconnects, nor can the soldering process used to form the connections. Advanced chip packaging techniques must therefore be employed, including interposers, to bridge this dimensional gap.

In addition to providing a dimensional bridge between chip level and board level interconnects, chip packaging also serves to provide environmental protection and thermal dissipation for the semiconductor die. While monolithically integrated System-on-Chip (SoC) dies are facing significant manufacturing costs, chip packaging also provides a more economically favorable opportunity to heterogeneously integrate multiple smaller dies into a single comparable System-in-Package (SiP). Due to increasing manufacturing costs at lower transistor nodes, decreasing yields for large die sizes, and complex non-recurring engineering costs of SoC's, the cost advantage of SiP's is growing. While transistor sizes have continued to shrink, however, the size of packaging technologies has not kept pace. This trend in packaging size is now occasionally referred to as the Moore's Law of packaging.

One common approach in heterogeneous die integration is the use of an interposer, a platform of high density metal interconnects pattered into a substrate such as silicon or glass. Notably, these interconnects can be patterned using semiconductor fabrication techniques, and therefore able to more closely match the size and pitch of chip level interconnects. The role of the interposer is to then scale and redistribute these interconnects up to the board level. Multiple chips can be integrated onto a single interposer in this manner. Drawbacks of modern interposers are that they can be expensive, fragile, size constrained, rigid, temperature constrained, and in the end must still be mounted to a printed circuit board.

While printed circuit boards are relatively low cost, and convenient for manufacturing and testing, they remain large, thick, and often have mismatched coefficients of thermal expansion relative to the silicon-based componentry. The interposer architecture, as a platform, in essence could contain the same circuitry as a PCB, but to date, interposers are too expensive and brittle to be used as a replacement. A low cost, thin, and durable interposer-like platform would offer the opportunity to avoid PCBs altogether.

### SUMMARY OF THE INVENTION

The present invention discloses, in an embodiment, an architecture of a System-on-Foil device with an electrically conductive foil substrate, onto which one or more intermediate layers are applied, followed by one or more patterned high-density metal interconnect layers. The uppermost interconnect layer provides a connective platform onto which one or more semiconductor dies are mounted and integrated. Passive electronic components may also be mounted to this platform. The package is encapsulated to produce a fully functional System-on-Foil device. Through-substrate-holes may be utilized to connect the System-on-Foil circuitry to electrical pads to facilitate external connection.

The present invention discloses, in an embodiment, an architecture of a System-on-Foil device with an electrically conductive foil substrate, onto which one or more intermediate layers are applied, followed by a thin-film semiconductor layer. Semiconductor fabrication processes may be used to pattern functional active and passive features, including transistors, into this semiconductor layer. One or more metal interconnect layers are fabricated on top of the semiconductor layer and connect to the active features in the semiconductor layer. The uppermost interconnect layer provides a connective platform onto which one or more semiconductor dies are mounted and integrated. Passive electronic components may also be mounted to this platform. The package is encapsulated to produce a fully functional System-on-Foil device. Through-substrate-holes may be utilized to connect the System-on-Foil circuitry to electrical pads to facilitate external connection.

### BRIEF DESCRIPTION OF THE DRAWINGS

FIG. 1a is a perspective view of a semiconductor film(s) (102), which itself may be patterned, on an intermediate film(s) (101) on a supporting electrically conductive substrate (100);

FIG. 1b is a perspective view of a semiconductor film(s) (102), which itself may be patterned, on an intermediate film(s) (101) on a supporting electrically conductive substrate (100) that are separated from each other for clarity;

FIG. 2a is a perspective view of an interconnect layer(s) (202) on an intermediate film(s) (101) on a supporting electrically conductive substrate (100);

FIG. 2b is a perspective view of an interconnect layer(s) (202) on an intermediate film(s) (101) on a supporting electrically conductive substrate (100) that are separated from each other for clarity;

FIG. 3a is a perspective view of a surface mounted or printed component(s) (301) on a metal interconnect layer(s) (202) on an intermediate film(s) (101) on a supporting electrically conductive substrate (100);

FIG. 3b is a perspective view of a surface mounted or printed component(s) (301) on a metal interconnect layer(s) (202) on an intermediate film(s) (101) on a supporting electrically conductive substrate (100) that are separated from each other for clarity;

FIG. 4a is a perspective view of a metal interconnect layer(s) (202) on a semiconductor layer(s) (102), which may be patterned to include active features, on an intermediate film(s) (101) on a supporting electrically conductive substrate (100);

FIG. 4b is a perspective view of a interconnect layer(s) (202) on a semiconductor layer(s) (102) which may be patterned to include active and/or passive components, on an intermediate film(s) (101) on a supporting electrically conductive substrate (100) that are separated from each other for clarity;

FIG. 5a is a perspective view of a surface mounted or printed component(s) (301) on an interconnect layer(s) (202) on a semiconductor layer(s) (102), which itself may be patterned to include active and/or passive components that are connected to the interconnect layer, on an intermediate film(s) (101) on a supporting electrically conductive substrate (100);

FIG. 5b is a perspective view of a surface mounted or printed component(s) (301) on an interconnect layer(s) (202) on a semiconductor layer(s) (102) which itself may be patterned to include active and/or passive components that are connected to the interconnect layer, on an intermediate film(s) (101) on a supporting electrically conductive substrate (100) that are separated from each other for clarity;

FIG. 6a is a perspective view of a System-on-Foil device, comprising of an encapsulation layer (600) on or around a surface mounted or printed component(s) (301) on an interconnect layer(s) (202) on a semiconductor layer(s) (102), which itself may be patterned to include active and/or passive components, on an intermediate film(s) (101) on a supporting electrically conductive substrate (100);

FIG. 6b is a perspective view of a System-on-Foil device, comprising of an encapsulation layer (600) on or around a surface mounted or printed component(s) (301) on an interconnect layer(s) (202) on a semiconductor layer(s) (102), which itself may be patterned to include active and/or passive components, on an intermediate film(s) (101) on a supporting electrically conductive substrate (100) that are separated from each other for clarity;

FIG. 7a is a perspective view of a System-on-Foil device (701) mounted to an external structure or circuit (700) and connected via an electrical connection(s) (702); and

FIG. 7b is a perspective view of a System-on-Foil device (701) mounted to an external structure or circuit (700) and connected via an electrical connection(s) (702), that are separated from each other for clarity.

### DETAILED DESCRIPTION OF THE INVENTION

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention. The present invention concerns an electrical device comprising an electrically conductive supporting substrate (100), at least one intermediate layer (102) on the substrate, at least one interconnect layer (101), and at least one surface mounted electrical component (301).

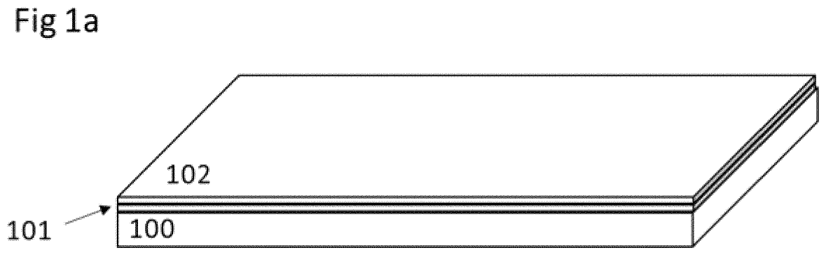

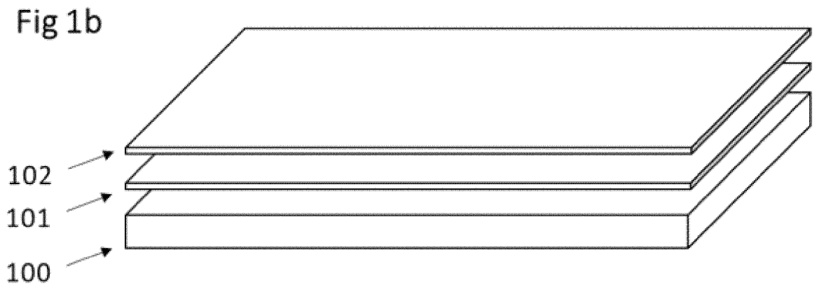

Referring to FIGS. 1a and 1b, an electrically conductive substrate (100) may comprise a sheet or foil of an electrically conductive material, such as but not limited to the following elements or alloys substantially comprising thereof Al, C, Co, Cu, Fe, Mo, W, Ta, Ti, or stainless steel. The electrically conductive substrate serves as a mechanical support for the device. The electrically conductive material may have a thickness of 5-1000 μm (e.g. 5 μm to 10 μm, 300 μm to 500 μm, or any other value or range of values therein). Preferably, the thickness of the electrically conductive substrate will grant the device a degree of mechanical flexibility. As such, a suitable substrate material should possess a softening point above processing temperatures for subsequent layers. These processing temperatures may be in the range of 350-1450° C. The electrically conductive substrate (100) may have any shape, such as circular, square, rectangular, oval, oblong, etc. The electrically conductive substrate (100) may also contain one or more hole(s) and or gap(s), such as vias or through-holes that allow a conductive layer to contact other layers or components in the device. The average surface roughness (Ra) of the electrically conductive substrate (100) should be less than 1 um to allow subsequent layers to conformally cover the electrically conductive substrate (100) and successful application of semiconductor fabrication processes. Electro, mechanical, chemical polishing, or a combination thereof may be employed to achieve a suitable surface roughness. Spin-on-glasses may also be used to obtain a suitable surface roughness. Prior to device assembly, the electrically conductive substrate may be cleaned to remove surface contaminants. Suitable surface cleaning techniques include the use of organic solvents such as methanol, isopropanol, or acetone, or acids such as nitric acid or hydrofluoric acid. Additionally, ultrasonic vibrations may be used in conjunction with the aforementioned cleaning chemicals. Plasma cleaning techniques, such as sputter plasma cleaning or reactive ion etching may also be employed to remove surface contaminants on the electrically conductive substrate. The electrically conductive substrate can also serve as a power plane and or ground plane, and be used to perform substrate biasing and or power gating.

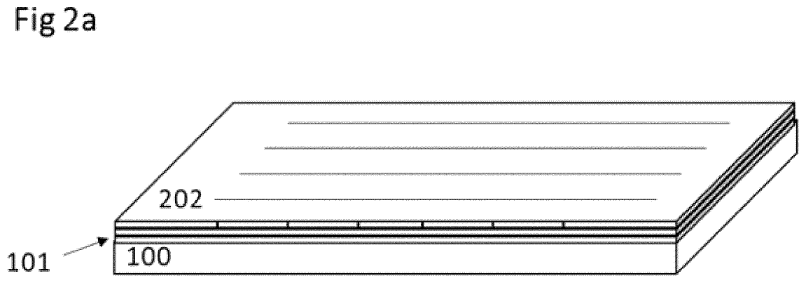

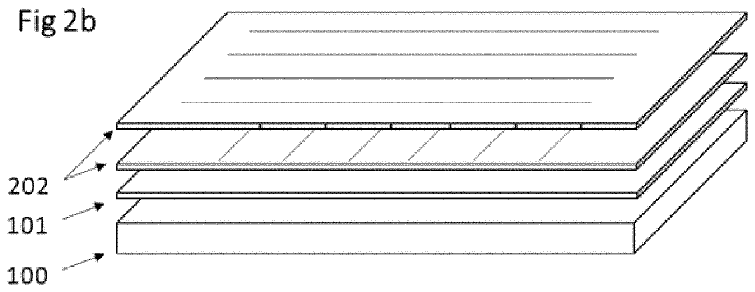

Referring to FIGS. 1 and 2, at least one intermediate layer (101) exists between the electrically conductive substrate (100) and the semiconducting layer(s) (102) or interconnect layers(s) (202). A intermediate layer (101) may consist of one or more metal(s), metal alloy(s), carbide(s), silicide(s), oxide(s), nitride(s), and or oxynitride(s) such as but not limited to Al, AlN, Al₂O₃, CeO₂, Cu, HfO₂, In₂O₃, NiSi, SiC, SiN, SiO₂, Ta, W, WC, W₂N, ZrO₂, etc. A suitable intermediate layer (101) material should withstand processing temperatures in the range of 350-1450° C., depending on other materials in the device, with minimal phase or chemical changes. An intermediate layer (101) may have a thickness in the range of 5 nm to 50 μm. The intermediate layer (101) may serve several purposes in the device, such as but not limited to: electrically isolating the electrically conductive substrate (100), improving adhesion of layers in the device, decreasing the diffusion of diffusing species between layers, modifying lattice mismatch stress between layers, managing thermal expansion induced stress, facilitating signal transmission, and providing power and thermal distribution. The intermediate layer (101) can also serve as a power plane and or ground plane, and be used to perform substrate biasing and or power gating. The intermediate layer (101) may be formed by deposition processes such as solution-based deposition (i.e. spin coating, printing, etc.), sputtering, evaporative deposition, pulsed laser deposition, hydride vapor phase epitaxy, atomic laser deposition, chemical vapor deposition or plasma-enhanced chemical vapor deposition. The intermediate layer (101) may be deposited to the top, bottom or both top and bottom of the device. After deposition, anneals may be performed to improve the quality of the intermediate layer(s) through mechanisms such as defect elimination, outgassing and or densification.

Referring to FIG. 1, a semiconductor layer (102) may be added on top of an intermediate layer (101). The semiconductor layer(s) may consist of one or more semiconducting materials, such as but not limited to: Si, Ge, SiGe, GaN, SiC, GaAs, InGaAs, perovskites, carbon nanotubes, and alloys thereof. The semiconductor layer(s) may be amorphous, crystalline, nanocrystalline or a combination thereof. The semiconductor layer thickness may range from 10 nm to 100 μm. The semiconductor layer may exist on top, on bottom, or both top and bottom of the device. The semiconductor layer allows the formation of one or more devices as transistors, diodes or other active or passive electrical devices in each layer to form components that may include but are not limited to switches, microcontrollers, microprocessors, voltage regulators, converters, interfaces, translators, level shifters, input/output expanders, power rails, etc. In one embodiment, at least one semiconducting film uniform in composition and thickness across the substrate is deposited through solution-based deposition (i.e. spin coating, printing, etc), sputtering, evaporative deposition, or chemical vapor deposition, as depicted in FIGS. 1a and 1b. In another embodiment, the semiconductor layer (102) exists in at least one selected area on the preceding intermediate layer (101), as depicted in FIGS. 1a and 1b. In this embodiment, adjacent areas in the semiconductor layer (102) may differ in thickness and composition. For example, a semiconductor layer (102) may consist of one area of Si 500 nm thick, and another area of SiGe 250 nm thick.

Referring to FIGS. 1a and 1b, the intermediate layer may also be patterned. In such an embodiment, one or more intermediate layer architectures may exist adjacent to each other. In an exemplary embodiment, a 100 nm MgO intermediate layer (101) may be deposited to cover an area of an electrically conductive substrate (101). A 50 nm Ta intermediate layer (101) may also be deposited to cover a different area on the electrically conductive substrate. The area covered by the 50 nm Ta intermediate layer (101) may be separate from the area covered by the 100 nm MgO intermediate layer (101), or the two areas may partially or completely overlap. In the exemplary embodiment, a 1 μm silicon semiconductor layer (102) may exist atop the 100 nm MgO intermediate layer (101), while a 2 μm GaN semiconductor layer (102) may exist atop the 50 nm Ta intermediate layer (101). Such an embodiment would allow an intermediate layer (101) to be compatible with semiconductor layer(s) (102) of multiple compositions. In this embodiment, devices to support one function, e.g. RF communications, may exist on the 2 μm GaN semiconductor layer (102) adjacent to devices that support another function, e.g. logic, in the 1 μm Si semiconductor layer (102). In this embodiment, lithographic techniques, such as direct write photolithography, mask-based photolithography, and nanoimprint lithography, and/or film patterning techniques, such as lift-off or etching, may be used in concert with thin film deposition techniques, such as solution-based deposition (i.e. spin coating, printing, etc), sputtering, evaporative deposition, pulsed laser deposition, hydride vapor phase epitaxy, atomic laser deposition, chemical vapor deposition or plasma-enhanced chemical vapor deposition. Following deposition, thermal anneals may be performed to enhance material properties by means such as crystallization, defect elimination, outgassing or densification.

In other embodiments, at least one semiconductor layer (102) may exist immediately atop another semiconductor layer, as depicted in FIGS. 1a and 1b. These layers may be patterned and may comprise of multiple semiconductors of varying thickness. The semiconductor layer(s) may exist in their intrinsic forms or be doped to achieve desired electrical properties. The semiconductor layer(s) may include dopants as-deposited, or dopants may be inserted into the layer after deposition, through processes such as dopant ion implantation. In an embodiment, a SiC semiconductor layer (102) may exist immediately atop a Si semiconductor layer (102). In this embodiment, the Si semiconductor layer (102) may provide a template for epitaxial growth of the subsequent SiC layer semiconductor layer (102). In this embodiment, semiconductor devices may be fabricated in either the Si semiconductor layer (102) or SiC semiconductor layers (102), or in both the Si semiconductor layer (102) and SiC semiconductor layers (102).

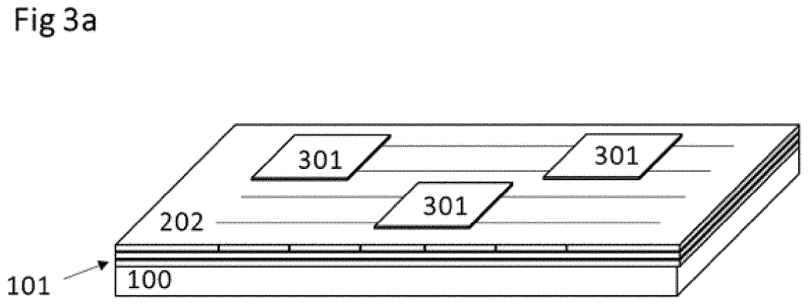

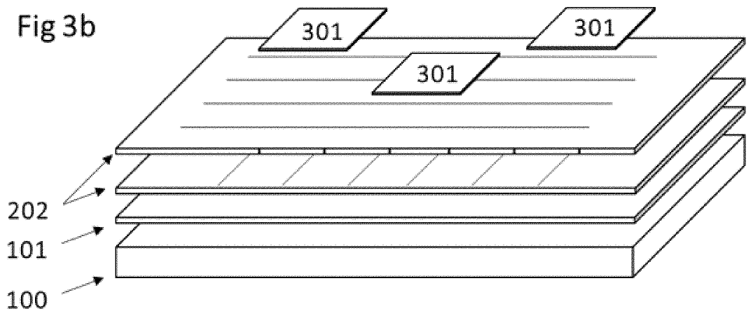

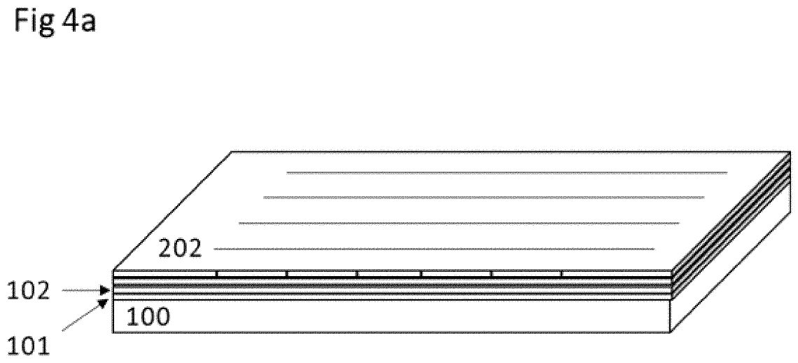

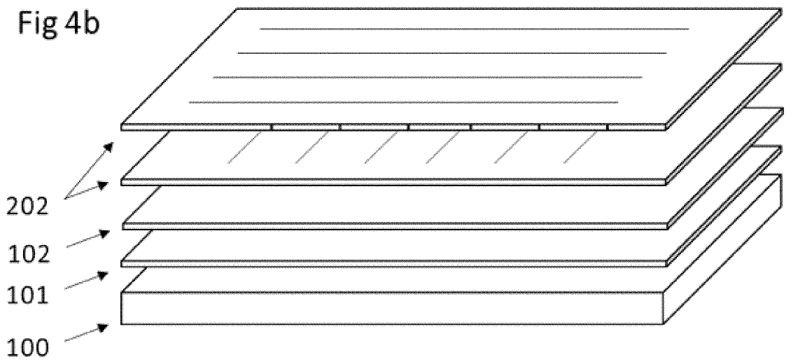

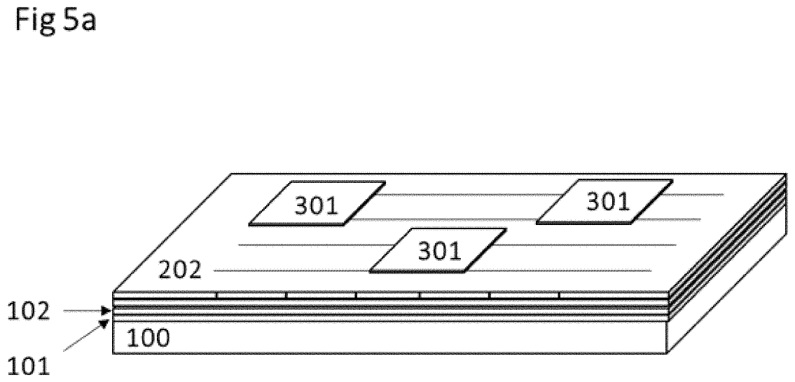

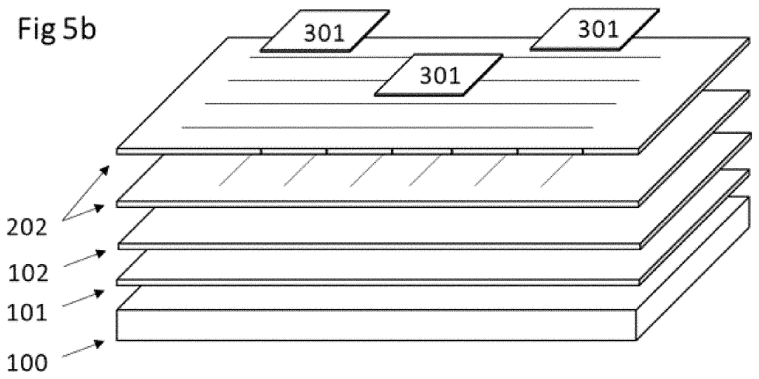

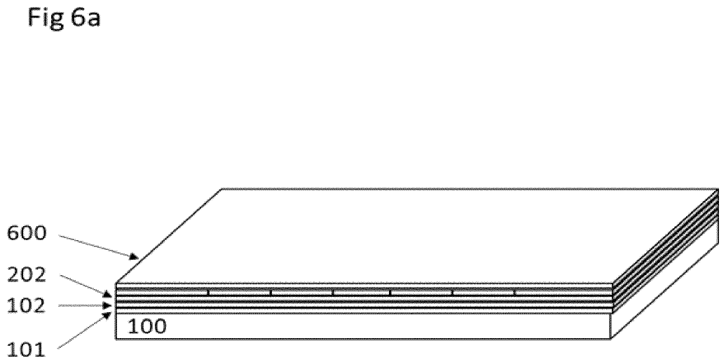

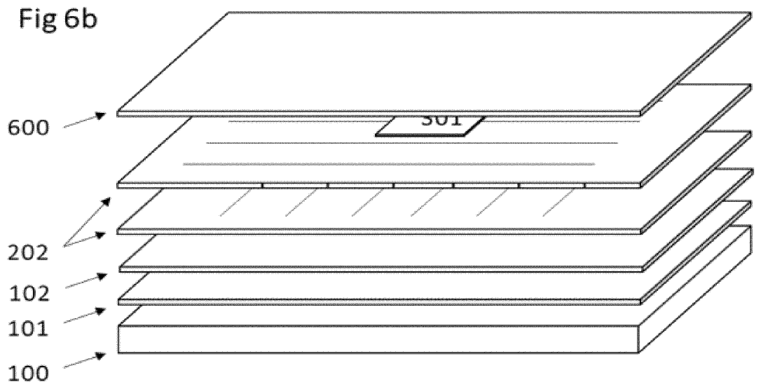

In other embodiments, at least one interconnect layer (202) may exist immediately atop another intermediate layer or semiconductor layer, as depicted in FIGS. 2 and 4. These layers may be patterned and may comprise of multiple metals and dielectrics of varying thickness. The interconnect layer(s) (202) may include passive electrical components. In an embodiment, a patterned Cu metal layer (202) may exist immediately atop another patterned Cu layer (202). In this embodiment, and as depicted in FIGS. 3 and 5, the Cu metal layer(s) (202) may act as electrical interconnects between patterned active or passive electrical components in a semiconductor layer (102), between surface mounted electrical components (301), or between both patterned active or passive electrical components in a semiconductor layer (102) and surface mounted electrical components (301).

In yet another embodiment, surface mounted electrical components may exist atop intermediate layer(s) (101) or semiconducting layers, as depicted in FIGS. 5a and 5b. Examples of these components include but are not limited to sensors, microcontrollers, microprocessors, radio frequency devices, power management devices, memory, field programmable gate arrays, solution deposited communications antenna, light emitting diodes, organic light emitting diodes, quantum dots, etc. In this embodiment, electrical components would add to the functionality of the semiconductor layer, if present. In one exemplary embodiment, an inkjet printed radio antenna may be used to transmit data generated by devices within the semiconducting layer. Through holes or vias in the electrically conductive substrate (100) would allow connectivity between devices on opposing sides of the substrate.

The above described device allows the union of the advanced functionality of semiconductor-based components with surface mounted electrical components and or printed components on a mechanically durable platform. For example, components in the semiconductor layer may add logic, data storage, power management, energy harvesting, or display capabilities to the device. Whereas surface mounted components or printed components on the device may add capabilities such as wireless communication, sensing or enhance interconnectivity of other components on the device.

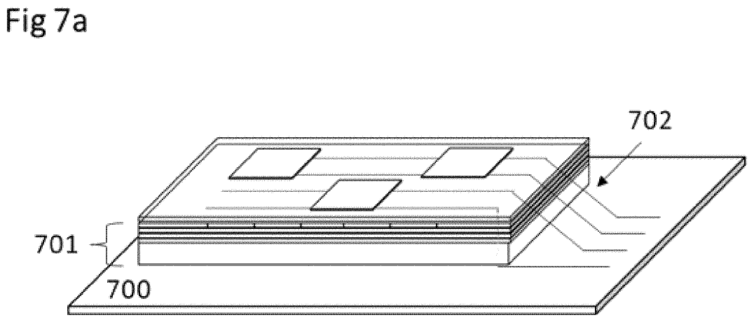

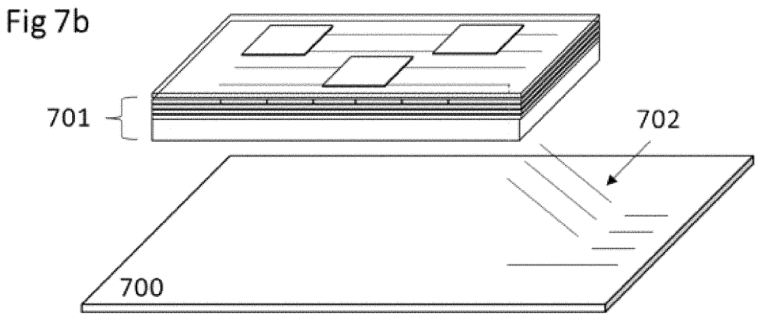

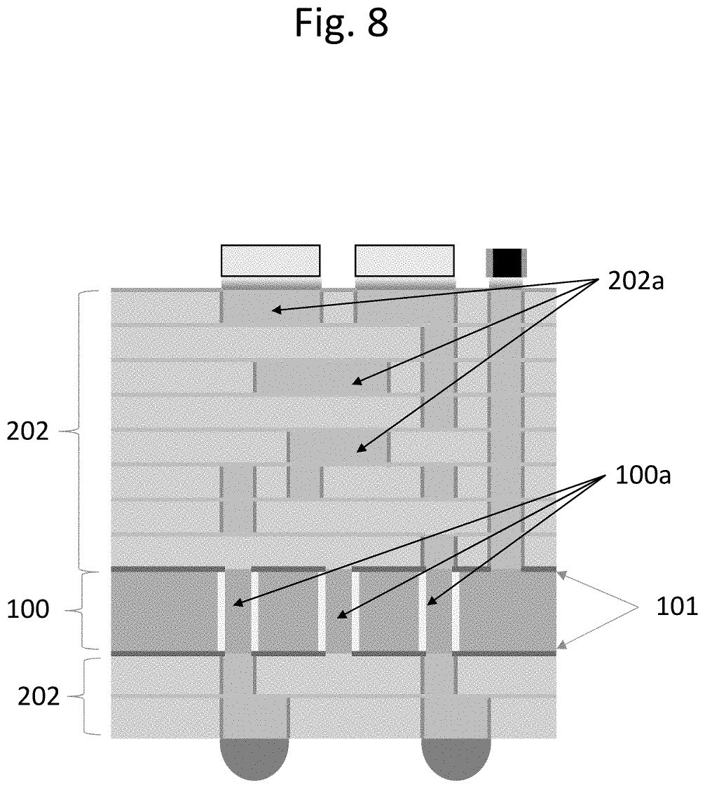

In yet another embodiment, referring to FIGS. 7a and 7b, the device (701) may be physically integrated and electrically connected to external structures or circuits (700). In one exemplary embodiment, the device is directly mounted and connected via an electrical connection(s) (702) to a flexible circuit built (700) on a flexible substrate instead of the usual printed circuit board. Integration approaches include but are not limited to tape automatic bonding (TAB), chip on film (COF), etc.

1-20. (canceled)

21. A semiconductor integrated platform system, comprising:
an intrinsically electrically conductive substrate;
at least one intermediate layer disposed on at least one of the top and the bottom surfaces of the electrically conductive substrate; and
at least one interconnect layer disposed on the at least one intermediate layer, the at least one interconnect layer including electrical components attached thereto.

22. The system according to claim 21, wherein the at least one intermediate layer is patterned, printed or selectively deposited to form a specific geometry.

23. The system according to claim 22, wherein the intrinsically electrically conductive substrate is configured with a plurality of isolated electrically conductive contacts formed therethrough.

24. The system according to claim 22, wherein the electrically conductive substrate is configured with a plurality of dielectric through-hole regions formed therethrough.

25. The system according to claim 22, wherein the electrically conductive substrate is configured with a plurality of isolated electrically conductive contacts formed therethrough and a plurality of dielectric through-hole regions formed therethrough.

26. The system according to claim 25, further comprising:
an encapsulating material that encapsulates at least a portion of the system.

27. The system according to claim 21, wherein the electrically conductive substrate is intrinsically formed of a sheet or a foil consisting substantially of one or more of the following metals or alloys: Al, C, Co, Cu, Fe, Mo, W, Ta, Ti, and stainless steel.

28. The system according to claim 21, wherein the at least one intermediate layer includes one or more metal(s), metal alloy(s), carbide(s), silicide(s), oxide(s), nitride(s), and or oxynitride(s) such as Al, Ta, W, Cu, WC, SiC, NiSi, SiO2, Al2O3, CeO2, ZrO2, HfO2, In2O3, Si3N4, AlN, and W2N.

29. The system according to claim 21, wherein the at least one interconnect layer includes one or more metals including Al, Co, Cu, Pt, Ru, Ti, Ta, and W, one or more dielectrics including silicates, SiO2, doped and undoped silicate glasses, TaN, and TiN, and semiconductors including silicides, and doped and undoped Si.

30. The system according to claim 21, wherein the at least one component attached to the least one interconnect layer is in communication with at least one other component attached to the at least one interconnect layer or to at least one component connected to an external circuit.

31. The system according to claim 21, wherein the intrinsically electrically conductive substrate is configured with a plurality of isolated electrically conductive contacts formed therethrough.

32. The system according to claim 21, wherein the electrically conductive substrate is configured with a plurality of dielectric through-hole regions formed therethrough.

33. The system according to claim 21, wherein the electrically conductive substrate is configured with a plurality of isolated electrically conductive contacts formed therethrough and a plurality of dielectric through-hole regions formed therethrough.

34. The system according to claim 21, further comprising:
at least one semiconductor layer disposed between the at least one intermediate layer and the at least one interconnect layer.

35. The system according to claim 34, wherein the electrically conductive substrate is configured with isolated electrically conductive contacts formed therethrough.

36. The system according to claim 34, wherein the electrically conductive substrate is configured with a plurality of dielectric through-hole regions formed therethrough.

37. The system according to claim 34, wherein the electrically conductive substrate is configured with isolated electrically conductive contacts formed therethrough and dielectric through-hole regions formed therethrough.

38. The system according to claim 34, wherein the at least one interconnect layer includes circuit components connected thereto.

39. The system according to claim 34, wherein the at least one semiconductor layer comprises Si, Ge, SiGe, SiC, GaAs, GaN, carbon nanotubes, perovskites, and/or alloys thereof.

40. The system according to claim 37, wherein the at least one semiconductor layer includes active and passive circuit components patterned therein.

41. The system according to claim 40, wherein predetermined ones of the active and passive circuit components in the at least one semiconductor layer are in communication with at least one other active or passive component in the at least one semiconductor layer or at least one component connected to an external circuit.
